(19) United States
(12) Patent Application Publication
(10) Pub. No.: US 2026/0142453 A1
(43) Pub. Date: May 21, 2026

(54) DESATURATION HIGH FREQUENCY CYCLE-BY-CYCLE CURRENT LIMIT

(71) Applicant: Cummins Inc., Columbus, IN (US)

(72) Inventor: James Douglas Bucher, II, Rogers, MN (US)

(21) Appl. No.: 18/954,203

(22) Filed: Nov. 20, 2024

(51) Int. Cl. H02H 9/02; H02H 1/00; H03K 3/037; H03K 19/20

(52) U.S. Cl. CPC H02H 9/02; H02H 1/0007; H03K 3/037; H03K 19/20

(57) ABSTRACT

An apparatus includes a switching device configured to turn on and off. A driver is operatively coupled with the switching device and is configured to configured to receive a command signal, output a control signal in response to the command signal to turn the switching device on and off, receive an input indicative of an desaturation condition of the switching device, and output a fault condition signal in response to the input. A state machine circuit including a bistable memory device operatively coupled with the driver and is configured to receive the fault condition signal and the command signal.

### BACKGROUND

The present application relates to apparatuses, systems, and processes including or providing desaturation current limits and more particularly, but not exclusively, including or providing high frequency cycle-by-cycle desaturation current limits.

When power semiconductor device such as an IGBT or MOSFET is completely on it is said to be saturated. A desaturation condition (also referred to herein as a desaturation fault, desat condition, or desat fault) occurs when the voltage across such a device is greater than a specified maximum voltage, causing excess power loss and excess current through the device thereby exceeding its maximum current rating. Such conditions can cause device failure we well as failure of associated components and equipment. Existing approaches to addressing or mitigating such conditions suffer from a number of disadvantages, shortcomings, and unmet needs including those respecting, complexity, efficacy, and efficiency, among others. There remains a significant need for the unique apparatuses, processes, and systems disclosed herein.

### DISCLOSURE OF EXAMPLE EMBODIMENTS

For the purposes of clearly, concisely, and exactly describing example embodiments of the present disclosure, the manner, and process of making and using the same, and to enable the practice, making and use of the same, reference will now be made to certain example embodiments, including those illustrated in the figures, and specific language will be used to describe the same. It shall nevertheless be understood that no limitation of the scope of the invention is thereby created, and that the invention includes and protects such alterations, modifications, and further applications of the example embodiments as would occur to one skilled in the art.

### SUMMARY OF THE DISCLOSURE

Some embodiments include apparatuses including desaturation current limits such as high frequency cycle-by-cycle desaturation current limits. Some embodiments include unique processes including desaturation current limits such as high frequency cycle-by-cycle desaturation current limits. Some embodiments include unique systems including desaturation current limits such as high frequency cycle-by-cycle desaturation current limits. Further embodiments, forms, objects, features, advantages, aspects, and benefits shall become apparent from the following description and drawings.

### BRIEF DESCRIPTION OF THE DRAWINGS

FIG. 1 is a schematic diagram depicting certain aspects of an example vehicle system.

FIG. 2 is a schematic diagram depicting certain aspects of example power electronics circuitry.

FIG. 3 is a schematic diagram depicting certain aspects of an example power converter.

FIG. 4 is a flow diagram depicting certain aspects of an example process.

FIG. 5 is a set of graphs depicting certain aspects of an example process.

FIG. 6 is graph depicting certain aspects of a cycle-by-cycle desaturation operation.

FIG. 7 is graph depicting certain aspects of another cycle-by-cycle desaturation operation.

### DETAILED DESCRIPTION OF EXAMPLE EMBODIMENTS

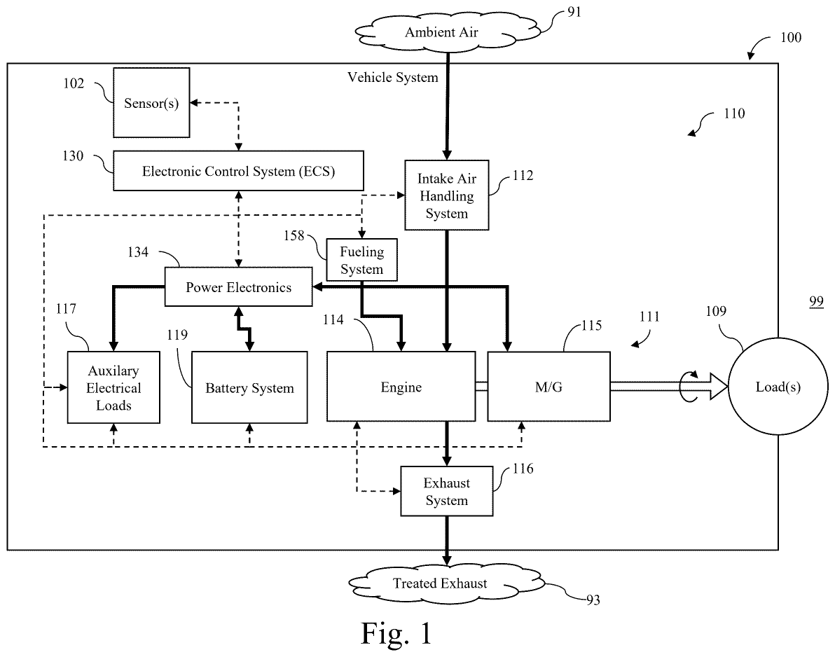

With reference to FIG. 1, there is illustrated an example system 100 including a powertrain system 110 (also referred to herein as system 110) including a prime mover system 111 configured to drive one or more loads 109. System 100 may be configured and provided in a number of forms. In the illustrated embodiment, system 100 is configured and provide in the form of a vehicle system, for example, an on-highway vehicle or an off-highway vehicle system. In other embodiments, system 100 may be configured and provided in the form of a work machine or work machine powertrain system, a genset or genset powertrain system, or a hydraulic fracturing rig or hydraulic fracturing rig powertrain system, to name several non-limiting examples. In shall be appreciated that system 100 may include a number of other components as will occur to one of skill in the art with the benefit and insight of the present disclosure. While system 100 is illustrated and described in the context of a powertrain system, it shall be appreciated that the present disclosure contemplates used in a variety of other systems including a power supply with a center-tapped output.

System 110 and prime mover system 111 may be configured and provided in a number of forms. In the illustrated example, system 110 and prime mover system 111 are configured and provided in a hybrid combustion-electric form including an internal combustion engine 114 and associated intake air handling system 112, exhaust system 116, and fueling system 158, and also including motor/generator (M/G) 115 and associated battery system 119 and power electronics 134. In other example embodiments, system 110 and prime mover system may be configured and provided as another type of prime mover system such as, for example, powertrains comprising battery electric prime mover systems, powertrains comprising fuel cell prime mover system, or other forms of powertrain and prime mover system as will occur to one of skill in the art with the benefit and insight of the present disclosure. In some such embodiments, internal combustion engine 114 and associated intake air handling system 112, exhaust system 116, and fueling system 158 may be omitted and the prime mover system pay be configured and provided in a battery electric form. It shall also be appreciated that system 110 may include a number of other components which are not depicted herein such as transmission systems and components, engine accessories, and other systems and components as will occur to one of skill in the art with the benefit and insight of the present disclosure.

In the illustrated embodiment, engine 114 is configured and provided in a four-stroke, compression ignition form. It shall be appreciated that engine 114 may be provided in a number of forms including spark ignition and liquid-spark ignition forms. Furthermore, in various forms, engine 114 may be configured for combustion of a number of fuels including, for example, diesel fuel, gasoline, natural gas, other gaseous hydrocarbons, hydrogen, alcohols, or other fuels or combinations of fuels as will occur to one of skill in the art with the benefit and insight of the present disclosure. Typical forms of engine 114 may include a block including a plurality of cylinders and a head coupled with the block. The head typically includes intake ports, intake valves configured to selectively open and close the intake ports, exhaust ports, exhaust valves configured to selectively open and close the exhaust ports, injector bores, fuel injectors disposed in the injector bores, spark plug bores, and spark plugs disposed in the spark plug bores. A plurality of pistons may be provided in respective ones of the plurality of cylinders. A crankshaft may be coupled with the plurality of pistons and configured to translate reciprocating motion of the plurality of pistons to provide torque for driving loads 109 which may include internal loads of system 110 (such oil pumps, valvetrains, fuel pumps and other loads of engine 114, and accessory loads of system 110). It shall be appreciated that system 110 may include a number of other components as will occur to one of skill in the art with the benefit and insight of the present disclosure.

Intake air handling system 112 may include one or more air handling conduits, air filters, compressors (such as a compressor of a turbocharger or supercharger), coolers (such as charger air coolers, intercoolers, and/or aftercoolers which may be, for example, of an air-to-air type or an air-to-liquid type), and sensors (such as temperature sensors, pressure sensors, mass flow sensors, and other types of sensors), as well as other components.

Exhaust system 116 may include one or more exhaust handling conduits, turbines (such as a turbine of a turbocharger), aftertreatment components (such as oxidation catalysts, particular filters, selective catalytic reduction (SCR) catalysts, and/or other catalysts and aftertreatment components), and sensors (such as temperature sensors, pressure sensors, oxygen or lambda sensors, mass flow sensors, and other types of sensors), as well as other components.

Fueling system 158 may be configured and provided as a high-pressure common-rail fuel injection system including a plurality of fuel injectors in fluid communication with a common fuel rail, which supplies fuel at relatively high pressure to the plurality of fuel injectors. Fuel may be supplied to the common fuel rail by a high-pressure pump which, in turn, may be fed by a relatively low-pressure fuel circuit including a booster pump, which may be immersed in a tank containing a reservoir of fuel.

In the illustrated embodiment, system 110 and prime mover system 111 are configured and provided in a parallel hybrid form in which motor/generator 115 can operate as a motor a powered by electricity from battery system 119 via power electronics 134 to output torque to drive loads either alone or in combination with torque output by engine 114, or as an electric generator driven by torque from engine 114 or regenerative braking, to generate and provide power via power electronics 134 to charge battery system 119.

In the illustrated embodiment, battery system 119 is configured and operable to output power via power electronics 134 to selectively power and drive either or both of motor/generator 115 and auxiliary electrical loads 117. Auxiliary electrical loads 117 may comprise any or a number of electrified vehicle loads including, for example, electrified fans, pumps, compressors, or other loads as will occur to one of skill in the art with the benefit and insight of the present disclosure.

System 110 includes an electronic control system (ECS) 130 which preferably includes one or more programmable microcontrollers of a solid-state, integrated circuit type, and one or more non-transitory memory media configured to store instructions executable by the one or more microcontrollers. For purposes of the present application the term microcontroller shall be understood to also encompass microprocessors and other types of integrated circuit processors. ECS 130 is in operative communication with and may be adapted and configured to control operation of and/or receive inputs from sensors or controllers of intake air handling system 112, engine 114, exhaust system 116, and fueling system 158. ECS 130 is in operative communication with and may be adapted and configured to control operation of and/or receive inputs from one or more system sensors 102 of system 100 which may include, for example, a throttle position sensor or an accelerator position sensor. It shall be appreciated that FIG. 1 depicts control relationships between the foregoing components conceptually using dashed arrows and that various communications hardware and protocols may be utilized to implement, such as one or more controller area networks (CAN) or other communications components.

ECS 130 can be implemented in any of a number of ways that combine or distribute the control function across one or more control units in various manners. The ECS 130 may execute operating logic that defines various control, management, and/or regulation functions. This operating logic may be in the form of dedicated hardware, such as a hardwired state machine, analog calculating machine, programming instructions, and/or a different form as would occur to those skilled in the art. The ECS 130 may be provided as a single component or a collection of operatively coupled components; and may be comprised of digital circuitry, analog circuitry, or a hybrid combination of both of these types. When of a multi-component form, the ECS 130 may have one or more components remotely located relative to the others in a distributed arrangement. The ECS 130 can include multiple processing units arranged to operate independently, in a pipeline processing arrangement, in a parallel processing arrangement, or the like. It shall be further appreciated that the ECS 130 and/or any of its constituent components may include one or more signal conditioners, modulators, demodulators, Arithmetic Logic Units (ALUs), Central Processing Units (CPUs), limiters, oscillators, control clocks, amplifiers, signal conditioners, filters, format converters, communication ports, clamps, delay devices, memory devices, Analog to Digital (A/D) converters, Digital to Analog (D/A) converters, and/or different circuitry or components as would occur to those skilled in the art to perform the desired communications.

An operating environment 99 is also depicted in FIG. 1. As described above, during typical operation of system 100, ambient air 91 of operating environment 99 is received as an input to system 100, and treated exhaust 93 from system 100 is released to operating environment 99. In some embodiments, loads 109 may at least in part comprise a portion of operating environment 99. For example, in embodiments where system 100 is provided in the form of a genset or genset powertrain system, the one or more loads 109 may comprise loads at various nodes in a distributed power network in addition to load components which, even if small, are integral to system 100. As another example, in embodiments where system 100 is provided in the form of a vehicle or vehicle powertrain system, loads 109 may include forces such as wind, gravity, road surface friction and other environmental load components in addition to load components which, even if small, are integral to system 100.

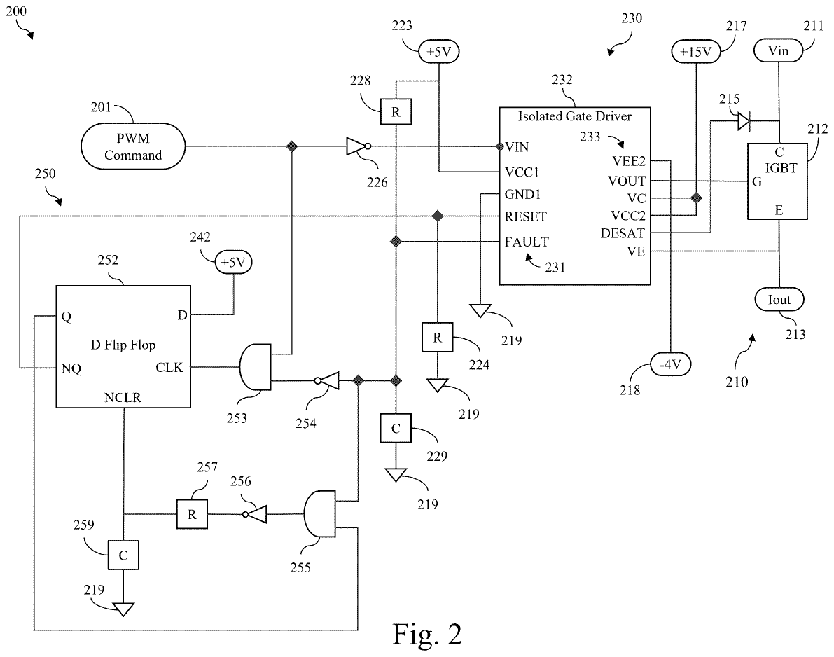

With reference to FIG. 2 there is illustrated example circuitry 200 which is configured and operable to provide a cycle-by-cycle limit when overload or excess current causes a switching device to come out of saturation. Circuitry 200 which may be implemented and provided in connection with power electronics 134 or with other suitable power electronics. In the illustrated example, circuitry 200 is depicted as including switching circuitry 210, driver circuitry 230, and state machine circuitry 250. It shall be appreciated that other embodiments may include additional and/or alternative components as will occur to one of skill in the art with the benefit and insight of the present disclosure. It shall be further appreciated that cycle-by-cycle current limit disclosed herein may be utilized in connection with any power electronics application including a driver with a desaturation feature that monitors the voltage across a semiconductor switch (for example, BPJ, MOSFET, SiCFET, GaNFET, or IGBT semiconductor switches) including but not limited to power supplies and inverters.

Switching circuitry 210 of circuitry 200 comprises switching device 212. In the illustrated example, switching device 212 comprises an insulated-gate bipolar transistor (IGBT) power semiconductor device. In other embodiments, switching device 212 may comprise other types of power semiconductor devices, for example, a metal-oxide-semiconductor field-effect transistors (MOSFET) such as a Silicon Carbide (SiC) MOSFET or other types of MOSFETs, a Gallium Nitride (GaN) device, or other types of power semiconductor device as will occur to one of skill in the art with the benefit and insight of the present disclosure.

In the illustrated example, switching device 212 includes a collector (C), an emitter (E), and a gate (G). In the illustrated example, collector (C) of switching device 212 is operatively coupled with input 211 supplying an input voltage (Vin). In other embodiments, collector (C) of switching device 212 may be coupled to another switching device, or a load. Emitter (E) of switching device 212 is operatively coupled with output 213 and supplies an output current (Iout) thereto. Gate (G) of switching device 212 is operatively coupled with and configured to receive a control signal from driver circuitry 230 which is effective to cause switching device 212 to turn on in response to an on value of the control signal and turn off in response to an off value of the control signal.

Driver circuitry 230 includes driver 232. In the illustrated example, driver 232 is configured and provided as an integrated circuit (IC)-based isolated gate driver with integrated desaturation fault detection, desaturation mode operation, and fault status feedback. It shall be appreciated that driver 232 may be configured and provided in various forms as will occur to one of skill in the art with the benefit and insight of the present disclosure.

Driver 232 includes a plurality of input-side pins 231. In the illustrated example, the plurality of input-side pins 231 include gate drive command input pin (VIN), positive supply voltage pin (VCC1), ground pin (GND1), reset input pin (RESET), and fault output pin (FAULT). In other embodiment the plurality of input-side pins 231 may comprise additional and/or alternative pins as will occur to one of skill in the art with the benefit and insight of the present disclosure.

The VIN pin of driver 232 is configured and operable to receive a command signal 201. In the illustrated example, command signal 201 is pulse width modulation (PWM) command signal which may be output by and received from a microcontroller, a pre-driver or other control components. Other embodiments contemplate other types of command signals as will occur to one of skill in the art with the benefit and insight of the present disclosure.

Inverter 226 is provided intermediate command signal 201 and the VIN pin and is configured to invert the value of command signal 201 such that a logical low value of command signal 201 is inverted to a logical high value of command signal 201, a logical high value of command signal 201 is inverted to a logical low value of command signal 201, a rising edge of value of command signal 201 is inverted to a falling edge, and a falling edge of value of command signal 201 is inverted to a rising edge. In other embodiments, a non-inverted form of command signal 201 may be provided to the VIN pin.

The VCC1 pin is operatively coupled with and receives positive input supply voltage 223. The GND1 pin is operatively coupled with logical ground 219. The RESET pin is configured and operable to receive a fault reset input from state machine circuitry 250 and is operatively coupled with circuitry of state machine circuitry 250 as further described elsewhere herein.

The FAULT pin is configured and operable to provide an output indicative of a fault condition of driver 232 and is operatively coupled with circuitry of state machine circuitry 250 as further described elsewhere herein. Driver 232 is configured and operable to change the output of FAULT pin from logical high to logical low in response to driver 232 receiving a signal at DESAT input indicative of a desaturation condition of switching device 212 which may also be associated with an over-current condition or fault. Thereafter, the output of the FAULT pin will remain low until the input to the RESET pin of driver 232 is brought low at which time the output of the FAULT pin will go high.

Driver 232 includes a plurality of output-side pins 233 In the illustrated example, the plurality of output-side pins 233 include negative supply voltage pin (VEE2), gate drive voltage output pin (VOUT), collector voltage pin (VC), positive supply voltage pin (VCC2), desaturation voltage input pin (DESAT), and emitter voltage pin the return and reference for VCC2, VE and VOUT. In other embodiment the plurality of output-side pins 233 may comprise additional and/or alternative pins as will occur to one of skill in the art with the benefit and insight of the present disclosure.

The VOUT pin is operatively coupled with gate (G) of switching device 212 and is configured and operable to output a control signal in the form of a gate drive voltage which is effective to turn switching device 212 on when the control signal or gate drive voltage is high or off when the control signal or gate drive voltage is low, it being appreciated that inverted or reversed on and off gate drive voltages maybe utilized in connection with certain forms of switching device 212.

The DESAT pin is operatively coupled with collector (C) by diode 215. When switching device 212 experiences and desaturation condition, the voltage provided to the DESAT pin exceeds a reference voltage indicating entry of driver 232 into a desaturation mode in response to a desaturation condition of switching device 212. In response, switching device 212 changes the output of the FAULT pin to logical low. It shall be appreciated that the DESAT pin may directly compare a received voltage with a reference voltage corresponding to a voltage drop (VCE) across the switching device 212. In some embodiments, driver 232 may be configured to identify a desaturation condition of switching device 212 using different inputs and bases for evaluating voltage drop VCE, for example, a direct comparison of a sensed voltage of collector (C) and emitter (E) of switching device 212.

The VEE2 pin is operatively coupled with negative output supply voltage 218. The VC pin and the VCC2 pin are operatively coupled with positive output supply voltage 217. In the illustrated example, VCC2 is the internal control voltage, VC is the drive collector voltage. In the case of a GaN VC would be 5V while VCC2 would be 15V. In the case of a MOSFET or SiCFET VC and VCC2 are connected together and utilize a common voltage. The VE pin is operatively coupled with emitter (E) of switching device 212.

State machine circuitry 250 is operatively coupled with driver circuitry 230 and is configured and operable in combination with other components of circuitry 200 to implement and provide high frequency cycle-by-cycle current limits in using a desaturation detection feature of driver circuitry 230. State machine circuitry 250 includes a bistable memory device which, in the illustrated example, is configured and provided in the form of D flip flop 252. Other embodiments may include other types of bistable memory devices such as other types of flip flops, amplifiers, multivibrators, latches and latching circuits, gate arrays, and other bistable memory devices as will occur to one of skill in the art with the benefit and insight of the present disclosure. It shall be appreciated that bistable memory devices according to the present disclosure may be provided as discrete components, such as active discrete components, and that such components may be configured and provided in various forms and packages including various integrated circuit (IC) forms and packages.

D flip flop 252 includes a data input (D) which is operatively coupled with reference voltage 242. Reference voltage 242 may be the same as or different from positive input supply voltage 223. In the illustrated example, reference voltage 242 is configured and provided as a logical high value. It shall be appreciated that the description herein of various values as logical high values and logical low values is by way of example, and that corresponding circuitry and devices may be provided with some or all of such logical high values and logical low values inverted or reversed in logical value, that is, logical high values may be substituted for logical low values, and vice-versa.

D flip flop 252 further includes clock input (CLK) which is configured to perform a clock operation in response to an input signal rising edge, inverted clear input (NCLR), noninverted output (Q), and inverted output (NQ). Clock input CKL is coupled with and configured to receive the output of AND logic gate 253. A first input of AND logic gate is coupled with and configured to receive command signal 201. A second input of AND logic gate 253 is coupled with FAULT pin of driver 232 by inverter 254 and is configured to receive the inverted logical value output by the FAULT pin of driver 232.

When driver 232 enters a desaturation mode in response to desaturation of switching device 212, the output of the FAULT pin is set to a logical low value, and the inverted logical high value is provided to the second input of AND logic gate 253. Under these conditions, a rising edge of command signal 201 will provide a logical high value to the first input of AND logic gate 253. AND logic gate 253 will then provide a logical high value to CLK input of D flip flop 252. In response, D flip flop will output a logical high value at its noninverted output Q and a logical low value at its inverted output NQ.

The logical low value of inverted output NQ of D flip flop 252 is provided to RESET pin of driver 232 causing the driver 232 to reset the fault latch. The fault latch causes the output (VOUT) of driver 232 to go low and the output will stay in that state until a RESET pulse is applied or power is removed. The logical high value of noninverted output Q of D flip flop 252 is provided to a first input of AND logic gate 255. A second input of AND logic gate 255 is coupled with FAULT pin of driver 232 which will go to at a logical low value in response to a desaturation fault.

When the fault latch of driver 232 is cleared, the output of FAULT pin of driver 232 will transition to logical high and the second input of AND logic gate 255 will also receive a logical high value. AND logic gate 255 will then output a logical high value to inverter 256. The output of inverter 256 is then provided to NCLR input of D flip flop 252 with a time delay established by the RC time constant of resistor 257 and capacitor 259. The resulting logical low signal provided to NCLR input of D flip flop 252 causes D flip flop 252 to reset. In response to such a reset the noninverting output Q of D flip flop 252 transitions to logical low, and the inverting output NQ of D flip flop 252 transitions to logical high. The D flip flop is thereby reset or restored to its initial condition and may repeat the aforementioned operations if driver 232 again enters a desaturation mode.

Circuitry 200 includes a number of additional discrete passive components including pull up resistor 224, a low pass filter comprising resistor 228 and capacitor 229 which are configured and operable to filter noise spikes. It shall be appreciated that other forms of circuitry 200 may include and utilize other arrangements of discrete passive components as will occur to one of skill in the art with the benefit and insight of the present disclosure.

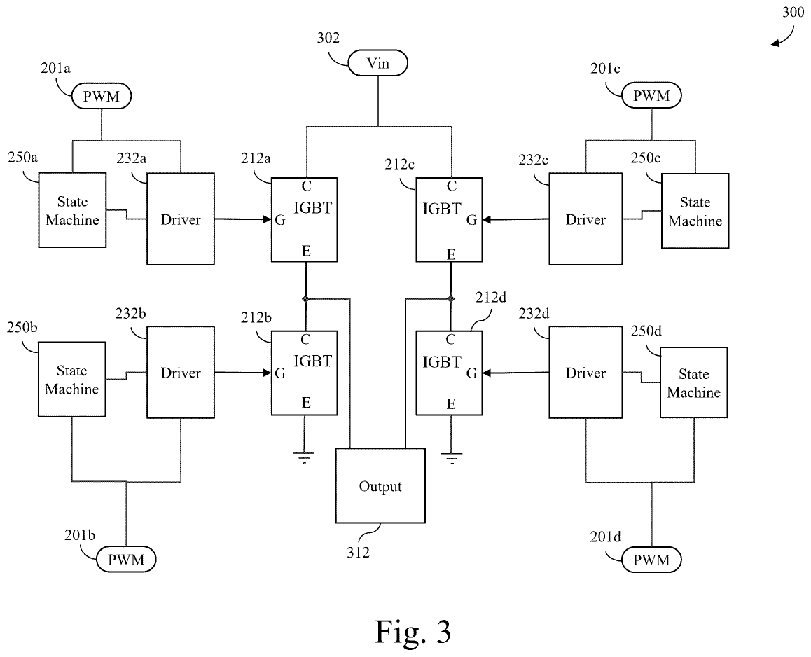

With reference to FIG. 3 there is illustrated an example power converter 300 which is configured and operable to provide high frequency cycle-by-cycle desaturation current limits. Power converter 300 may be implemented and provided in connection with power electronics 134 or with other suitable power electronics. In the illustrated example, power converter is configured and provided in the form of an H-bridge converter. It shall be appreciated that other embodiments may comprises other arrangement, configurations, and forms of power converters including, for example, DC-DC converters, inverters, rectifiers, bidirectional converters, and other types of power converters as will occur to one of skill in the art with the benefit and insight of the present disclosure.

Power converter 300 includes including switching devices 212a, 212b, 212c, and 212d which are arranged in an H-bridge configuration and may be configured and provided in and with the same or a similar forms and functions as switching device 212 and switching circuitry 210, as well as in other arrangements, configurations, and forms as will occur to one of skill in the art with the benefit and insight of the present disclosure.

The collectors (C) of switching device 212a and switching device 212c are operatively coupled with an input 302 which provides an input voltage (Vin) thereto. The emitters (E) of switching device 212a and switching device 212c are operatively coupled with the collectors (C) of switching device 212b and switching device 212d, respectively. The emitters (E) of switching device 212b and switching device 212d are operatively coupled with ground. An output 312 of power converter 300 is operatively coupled with a node intermediate switching device 212a and switching device 212b, and a node intermediate switching device 212c and switching device 212d.

Power converter 300 further includes drivers 232a, 232b, 232c, and 232d which are operatively coupled with and configured to provide control signals to switching devices 212a, 212b, 212c, and 212d, respectively. Drivers 232a, 232b, 232c, and 232d may be configured and provided in and with the same or a similar forms and functions as driver 232 and driver circuitry 230, as well as in other arrangements, configurations, and forms as will occur to one of skill in the art with the benefit and insight of the present disclosure.

Drivers 232a, 232b, 232c, and 232d are also operatively coupled with state machines 250a, 250b, 250c, and 250d, respectively. State machines 250a, 250b, 250c, and 250d may be configured and provided in the same or a similar form as state machine circuitry 250 as well as other arrangements, configurations, and forms as will occur to one of skill in the art with the benefit and insight of the present disclosure.

Command signals 201a, 201b, 201c, and 201d are provided to drivers 232a, 232b, 232c, and 232d, respectively, and are also provided to state machines 250a, 250b, 250c, and 250, respectively. During operation of power converter 300, the respective drivers and state machines associated with each of switching devices 212a, 212b, 212c, and 212d may operate in the same or a substantially similar manner as circuitry 200, as well as in other manners as will occur to one of skill in the art with the benefit and insight of the present disclosure.

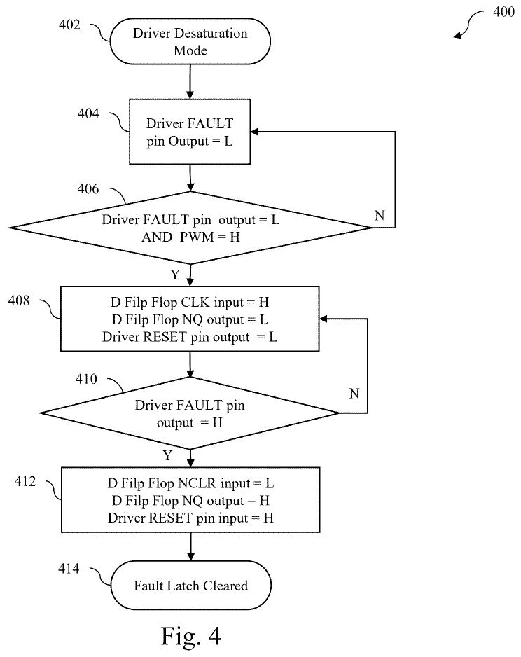

With reference to FIG. 4, there is illustrated an example process 400 which may be performed in a given cycle of an overall cycle-by-cycle current limit process using a driver desaturation fault detection feature. Process 400 may be performed during operation of circuitry 200 or other circuitry according to the present disclosure and may also be performed in during operation of a power converter such as power converter 300 or another power converter according to the present disclosure. For clarity, process 400 is described in connection with operation of circuitry 200, it being appreciated that similar processes may be concurrently performed for circuitry groupings of a power converter, as well as for multiple power converters of a given system.

Process 400 begins an operation 402 at which driver 232 enters a desaturation mode in response to a desaturation fault of switching device 212. From operation 402, process 400 proceed to operation 404 at which the FAULT pin output of switching device 212 is set to a logical low value. From operation 404, process 400 proceeds to conditional 406 which evaluates whether both the FAULT pin output of driver 232 is set to a logical low value and the value of command signal 201 is set to logical high as occurs on a rising edge of a PWM signal.

If conditional 406 evaluates negative, process 400 returns to operation 404 and proceeds as described above. If conditional 406 evaluates affirmative, process 400 proceeds to operation 408 at which the CLK input of D flip flop 252 is set to a logical high value. In response, the D flip flop 252 performs a clock operation, the NQ output of D flip flop 252 is set to a logical low value, and the Q output of D flip flop 252 and the input to the RESET pin of driver 232 are set to a logical low value, and the fault latch of the driver 232 is reset. From operation 408, process 400 proceeds to conditional 410 which evaluates whether FAULT pin output of driver 232 is set to a logical high value.

If conditional 410 evaluates affirmative, process 400 returns to operation 408 and proceeds as described above. If conditional 410 evaluates negative, process 400 proceeds to operation 412 at which at which the NCLR input of D flip flop 252 is set to a logical low value, and the Q output of D flip flop 252 and the input to the RESET pin of driver 232 are set to a logical high value. From operation 412, process 400 proceeds to operation 414 at which the desaturation mode of the driver is cleared. Process 400 thereafter ends and may subsequently repeat for a plurality of cycles to provide cycle-by-cycle current limits using a desaturation fault detection feature of driver 232.

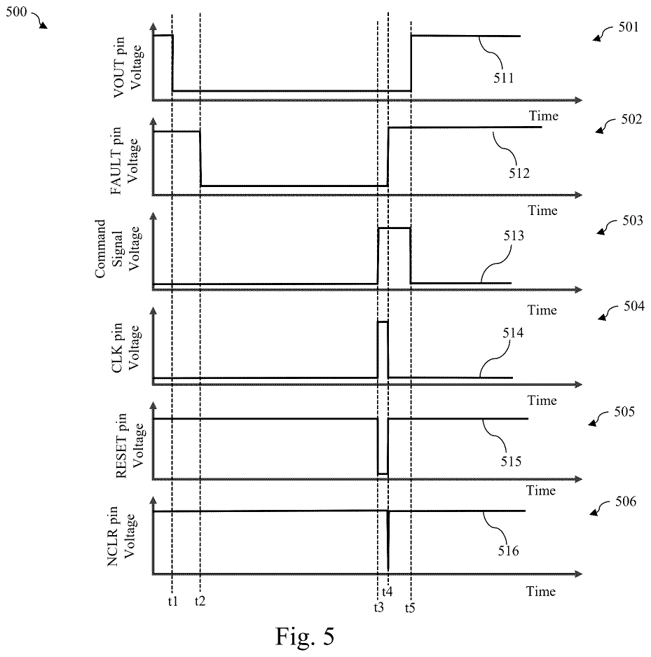

With reference to FIG. 5, there is illustrated a set of graphs 500 depicting certain aspects of a given cycle of an overall cycle-by-cycle current limiting operation using a desaturation feature of a driver configured to drive a power switching device. Graph 501 depicts curve 511 which is the voltage output at the VOUT pin of driver 232 as a function of time. In the illustrated example, the voltage at the VOUT pin of driver 232 goes low either when a received PWM command signal goes high and no desaturation fault is present, or when a desaturation fault causes the fault to latch of the driver and turn off the output. At time t1, driver 232 enters a desaturation mode in response to a desaturation condition of switching device 212 and the VOUT pin of driver 232 transitions from a logical high value to a logical low value. When the VOUT pin of driver 232 goes low, the desaturation condition is abated.

Graph 502 depicts curve 512 which is the voltage output at the FAULT pin of driver 232 as a function of time. After a time delay, at time t2, the voltage output at the FAULT pin of driver 232 transitions from a logical high value to a logical low value. The voltage output at the FAULT pin of driver 232 remains at a logical low value until a RESET pulse clears the fault. The FAULT pin transition to a high logical value is provided to AND gate 255 along with the Q output of D flip flop 252 causing a pulse at the NCLR input of D flip flop 252 causing the Q output of D flip flop 252 to transition to low logical value.

Graph 503 depicts curve 513 which is the voltage of the command signal 201 as a function of time. In the illustrated example, the command signal 201 is configured and provided as a PWM signal. At time t3, the voltage of the command signal 201 transitions from a logical low value to a logical high value as occurs at the rising edge of a PWM signal. At time t5 the voltage of the command signal 201 transitions from a logical high value to a logical low value as occurs at the falling edge of a PWM signal. In response, assuming a desaturation fault condition of driver 232 has been cleared, the voltage at the VOUT pin of driver 232 goes high.

Graph 504 depicts curve 514 which is the voltage at the CLK input of D flip flop 252 as a function of time. At time t3, the voltage at the CLK input of D flip flop 252 transitions from a logical low value to a logical high value in response to the voltage output at the FAULT pin of driver 232 being low and the voltage of the command signal 201 being high. In response the D flip flop 252 performs a clock operation which causes output NQ of D flip flop 252 to go low. At time t4, the voltage at the CLK input of D flip flop 252 transitions from a logical high value to a logical low value in response to the command signal 201 transitioning to a logical high value.

Graph 505 depicts curve 515 which is the voltage of the RESET pin of driver 232 as a function of time. At time t3, the voltage of the NQ output of D flip flop 252 transitions from a logical high value to a logical low value and the voltage of the RESET pin of driver 232 transitions from a logical high value to a logical low value which causes the driver 232 to reset the FAULT pin of driver 232 to go high. In response to the FAULT pin of driver 232 going high, the voltage at the CLK input of D flip flop 252 goes low.

Graph 506 depicts curve 516 which is the voltage of the NCLR input of D flip flop 252 as a function of time. At time t4, the voltage of the NCLR input of D flip flop 252 transitions from logical low to logical high and the D flip flop 252 is reset. This operation occurs in response to the command signal 201 transitioning to a logical high value.

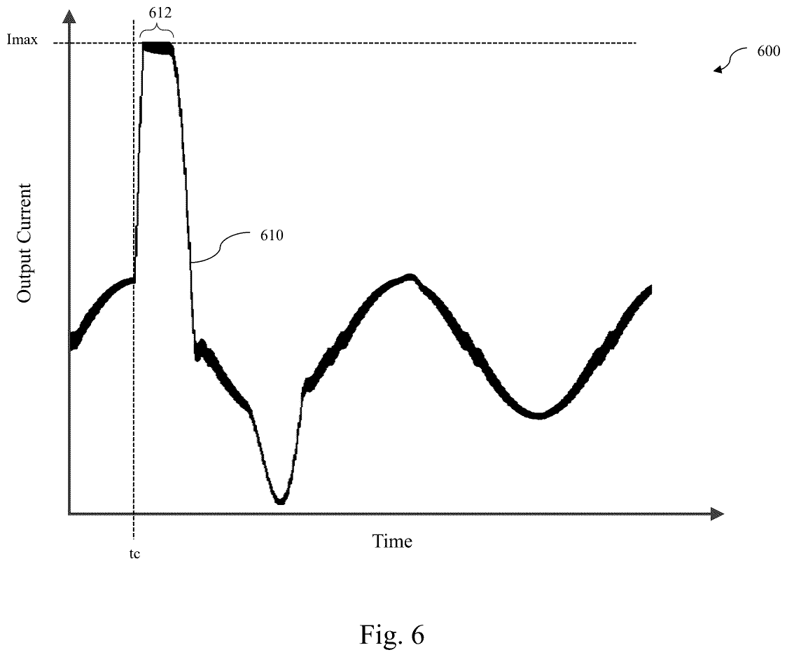

With reference to FIG. 6, there is illustrated an example graph 600, depicting a curve 610 of output current of a power converter as a function of time. In graph 600, the converter is connected with a capacitive load at or about time tc resulting in an inrush current. Region 612 of curve 610 depicts the current limit resulting from a high frequency cycle-by-cycle desaturation current limit on the resulting inrush current such as may be provided the embodiments disclosed herein. In region 612 a plurality of current limiting operations may be performed to limit the inrush current to a desired maximum level (Imax).

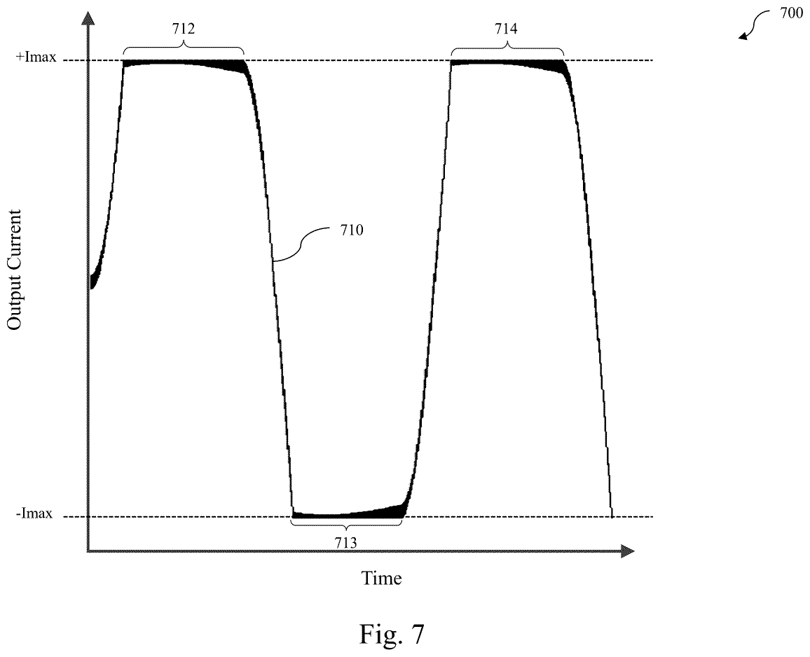

With reference to FIG. 7, there is illustrated an example graph 700, depicting a curve 710 of output current of a power converter as a function of time. In graph 700, a short circuit is present at the converter output or load connected therewith. Regions 712, 713, and 714 of curve 710 depicts the current limit resulting from a high frequency cycle-by-cycle desaturation current limit on the resulting short circuit currents such as may be provided the embodiments disclosed herein. In regions 712, 713, and 714 a plurality of current limiting operations may be performed to limit the short circuit current to desired maximum level, both positive (+Imax) and negative (Imax).

As illustrated by this detailed description, the present disclosure contemplates multiple embodiments including the following example embodiments.

Example embodiment 1 is an apparatus comprising: a switching device configured to turn on and off; a driver operatively coupled with the switching device, the driver being configured to receive a command signal, output a control signal in response to the command signal to turn the switching device on or off, receive an input indicative of a desaturation condition of the switching device, and, in response to the input, provide an output to turn off the switching device, set a fault latch, and output a fault condition signal; and a state machine circuit including a bistable memory device operatively coupled with the driver, the state machine circuit being configured to: receive the fault condition signal and the command signal, output a first state value from the bistable memory device to the driver in response to a first value of the fault condition signal indicating the desaturation condition of the switching device and a first value of the command signal indicating a command to turn the switching device off, the first state value providing an input to reset the fault latch of the driver, and output a second state value from the bistable memory device to the driver in response to a second value of the fault condition signal not indicating the desaturation condition of the switching device.

Example embodiment 2 includes the features of example embodiment 1, wherein the command signal comprises a pulse width modulation (PWM) signal and the command to turn the switching device off comprises a PWM pulse edge.

Example embodiment 3 includes the features of example embodiment 1, wherein the command signal and the fault condition signal are provided as inputs to an AND logic gate.

Example embodiment 4 includes the features of example embodiment 1, wherein the bistable memory device includes a first output operatively coupled with the driver and a second output operatively coupled with and providing a feedback signal to an input of the bistable memory device.

Example embodiment 5 includes the features of example embodiment 4, wherein second output is operatively coupled with the input by a delay circuit configured to delay the feedback signal.

Example embodiment 6 includes the features of example embodiment 5, wherein the delay circuit comprises at least one resistor and at least one capacitor configured to delay the feedback signal according to an RC time constant.

Example embodiment 7 includes the features of example embodiment 1, wherein the state machine circuit is configured to repeatedly output the first state value and the second state value over a plurality of cycles to operate the driver to provide a cycle-by-cycle current limit on current through the switching device.

Example embodiment 8 is a process of operating electrical circuitry including a switching device, a driver operatively coupled with the switching device, and a state machine circuit including a bistable memory device operatively coupled with the driver, the process comprising: providing a command signal to the driver and the state machine circuit, the command signal being configured to operate the driver to turn the switching device on or off; receiving with the driver an input indicative of a desaturation condition of the switching device; in response to the input, operating the driver to turn off the switching device, set a fault latch, and output a fault condition signal to the state machine circuitry, outputting a first state value from the bistable memory device to the driver in response to a first value of the fault condition signal indicating the desaturation condition of the switching device and a first value of the command signal indicating a command to turn the switching device off, resetting the driver to clear the fault latch in response to the first state value, and outputting a second state value from the bistable memory device to the driver in response to a second value of the fault condition signal not indicating the desaturation condition of the switching device.

Example embodiment 9 includes the features of example embodiment 8, comprising repeating the outputting the first state value and the outputting the second state value over a plurality of cycles to operate the driver to provide a cycle-by-cycle current limit on current through the switching device.

Example embodiment 10 includes the features of example embodiment 8, wherein the command signal comprises a pulse width modulation (PWM) signal and the command to turn the switching device off comprises a PWM pulse edge.

Example embodiment 11 includes the features of example embodiment 8, wherein the command signal and the fault condition signal are provided as inputs to an AND logic gate.

Example embodiment 12 includes the features of example embodiment 8, wherein the bistable memory device includes a first output operatively coupled with the driver and a second output operatively coupled with and providing a feedback signal to an input of the bistable memory device.

Example embodiment 13 includes the features of example embodiment 12, wherein second output is operatively coupled with the input by a delay circuit configured to delay the feedback signal.

Example embodiment 14 includes the features of example embodiment 13, wherein the delay circuit comprises at least one resistor and at least one capacitor configured to delay the feedback signal according to an RC time constant.

Example embodiment 15 is an apparatus comprising: a driver operatively coupled with a switching device, the driver being configured to receive a command signal, output a control signal in response to the command signal to turn the switching device on or off, receive an input indicative of an desaturation condition of the switching device, and to turn off, set a fault latch, and output a fault condition signal in response to the input; and a state machine circuitry operatively coupled with the driver, the state machine circuitry comprising: means for outputting a first state value in response to a first value of the fault condition signal indicating the desaturation condition of the switching device and a first value of the command signal indicating a command to turn the switching device off, and a second state value to the driver in response to a second value of the fault condition signal not indicating the desaturation condition of the switching device, the first state value providing an input to reset the fault latch of the driver.

Example embodiment 16 includes the features of example embodiment 15, wherein means for outputting is configured to repeatedly output the first state value and the second state value over a plurality of cycles to operate the driver to provide a cycle-by-cycle current limit on current through the switching device.

Example embodiment 17 includes the features of example embodiment 16, wherein the cycle-by-cycle current limit is effective to limit current during one or both of an inrush current to a load operatively coupled with the switching device and a short circuit fault of the load.

Example embodiment 18 includes the features of example embodiment 15, wherein the means for outputting comprises a bistable memory device.

Example embodiment 19 includes the features of example embodiment 18, wherein the bistable memory device comprises a flip flop.

Example embodiment 20 includes the features of example embodiment 19, wherein the flip flop comprises a D flip flop.

While example embodiments of the disclosure have been illustrated and described in detail in the drawings and foregoing description, the same is to be considered as illustrative and not restrictive in character, it being understood that only certain example embodiments have been shown and described and that all changes and modifications that come within the spirit of the claimed inventions are desired to be protected. It should be understood that while the use of words such as preferable, preferably, preferred or more preferred utilized in the description above indicates that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

1. An apparatus comprising:
a switching device configured to turn on and off;
a driver operatively coupled with the switching device, the driver being configured to receive a command signal, output a control signal in response to the command signal to turn the switching device on or off, receive an input indicative of a desaturation condition of the switching device, and, in response to the input, provide an output to turn off the switching device, set a fault latch, and output a fault condition signal; and
a state machine circuit including a bistable memory device operatively coupled with the driver, the state machine circuit being configured to:
receive the fault condition signal and the command signal,
output a first state value from the bistable memory device to the driver in response to a first value of the fault condition signal indicating the desaturation condition of the switching device and a first value of the command signal indicating a command to turn the switching device off, the first state value providing an input to reset the fault latch of the driver, and
output a second state value from the bistable memory device to the driver in response to a second value of the fault condition signal not indicating the desaturation condition of the switching device.

2. The apparatus of claim 1, wherein the command signal comprises a pulse width modulation (PWM) signal and the command to turn the switching device off comprises a PWM pulse edge.

3. The apparatus of claim 1, wherein the command signal and the fault condition signal are provided as inputs to an AND logic gate.

4. The apparatus of claim 1, wherein the bistable memory device includes a first output operatively coupled with the driver and a second output operatively coupled with and providing a feedback signal to an input of the bistable memory device.

5. The apparatus of claim 4, wherein second output is operatively coupled with the input by a delay circuit configured to delay the feedback signal.

6. The apparatus of claim 5, wherein the delay circuit comprises at least one resistor and at least one capacitor configured to delay the feedback signal according to an RC time constant.

7. The apparatus of claim 1, wherein the state machine circuit is configured to repeatedly output the first state value and the second state value over a plurality of cycles to operate the driver to provide a cycle-by-cycle current limit on current through the switching device.

8. A process of operating electrical circuitry including a switching device, a driver operatively coupled with the switching device, and a state machine circuit including a bistable memory device operatively coupled with the driver, the process comprising:
providing a command signal to the driver and the state machine circuit, the command signal being configured to operate the driver to turn the switching device on or off;
receiving with the driver an input indicative of a desaturation condition of the switching device;
in response to the input, operating the driver to turn off the switching device, set a fault latch, and output a fault condition signal to the state machine circuitry,
outputting a first state value from the bistable memory device to the driver in response to a first value of the fault condition signal indicating the desaturation condition of the switching device and a first value of the command signal indicating a command to turn the switching device off,
resetting the driver to clear the fault latch in response to the first state value, and
outputting a second state value from the bistable memory device to the driver in response to a second value of the fault condition signal not indicating the desaturation condition of the switching device.

9. The process of claim 8, comprising repeating the outputting the first state value and the outputting the second state value over a plurality of cycles to operate the driver to provide a cycle-by-cycle current limit on current through the switching device.

10. The process of claim 8, wherein the command signal comprises a pulse width modulation (PWM) signal and the command to turn the switching device off comprises a PWM pulse edge.

11. The process of claim 8, wherein the command signal and the fault condition signal are provided as inputs to an AND logic gate.

12. The process of claim 8, wherein the bistable memory device includes a first output operatively coupled with the driver and a second output operatively coupled with and providing a feedback signal to an input of the bistable memory device.

13. The process of claim 12, wherein second output is operatively coupled with the input by a delay circuit configured to delay the feedback signal.

14. The process of claim 13, wherein the delay circuit comprises at least one resistor and at least one capacitor configured to delay the feedback signal according to an RC time constant.

15. An apparatus comprising:
a driver operatively coupled with a switching device, the driver being configured to receive a command signal, output a control signal in response to the command signal to turn the switching device on or off, receive an input indicative of an desaturation condition of the switching device, and to turn off, set a fault latch, and output a fault condition signal in response to the input; and
a state machine circuitry operatively coupled with the driver, the state machine circuitry comprising:
means for outputting a first state value in response to a first value of the fault condition signal indicating the desaturation condition of the switching device and a first value of the command signal indicating a command to turn the switching device off, and a second state value to the driver in response to a second value of the fault condition signal not indicating the desaturation condition of the switching device, the first state value providing an input to reset the fault latch of the driver.

16. The apparatus of claim 15, wherein means for outputting is configured to repeatedly output the first state value and the second state value over a plurality of cycles to operate the driver to provide a cycle-by-cycle current limit on current through the switching device.

17. The apparatus of claim 16, wherein the cycle-by-cycle current limit is effective to limit current during one or both of an inrush current to a load operatively coupled with the switching device and a short circuit fault of the load.

18. The apparatus of claim 15, wherein the means for outputting comprises a bistable memory device.

19. The apparatus of claim 18, wherein the bistable memory device comprises a flip flop.

20. The apparatus of claim 19, wherein the flip flop comprises a D flip flop.
